(19) United States
(12) Patent Application Publication
(10) Pub. No.: US 2023/0213402 A1
(43) Pub. Date: Jul. 6, 2023

(54) METHOD OF MANUFACTURING A POROUS PRESSURE SENSOR AND DEVICE THEREFOR

(71) Applicant: Hermosa Optics Inc., Taichung City (TW)

(72) Inventor: Yen-Chih CHEN, Taichung City (TW)

(21) Appl. No.: 17/928,007

(22) PCT Filed: Jun. 2, 2020
(86) PCT No.: PCT/CN2020/093871

§ 371 Date: Nov. 28, 2022

(51) Int. Cl. G01L 9/08; H10N 30/076; H10N 30/077; H10N 30/04

(52) U.S. Cl. CPC G01L 9/08; H10N 30/076; H10N 30/077; H10N 30/04

(57) ABSTRACT

A method of manufacturing a porous pressure sensor, comprising: providing a substrate; forming a piezoelectric film on an upper surface of the substrate; performing a porosification process on the piezoelectric film, such as performing a wet etching process or a heat treatment process to form a porous pressure sensing layer; and forming a first electrode and a second electrode on two opposite sides of the upper surface of the porous pressure sensing layer, respectively. The present application is also directed to a pressure sensors manufactured by the method of manufacturing the porous pressure sensor.

### CROSS-REFERENCE TO RELATED APPLICATIONS

This application is a National Stage of International Application No. PCT/CN2020/093871, filed on Jun. 2, 2020, which is hereby incorporated by reference in its entirety.

### TECHNICAL FIELD

The present application relates to the field of pressure sensors, and more particularly relates to a method of manufacturing a porous pressure sensor and a device manufactured by the method.

### BACKGROUND

A pressure sensors is a sensor for measuring the pressure of liquids and gases, which is capable of converting the pressure applied into an electrical signal as a function of pressure. Historically, pressure sensors have been commonly used in automobiles, aircrafts, satellites, ships, diving equipment and weather forecasting equipment to measure atmospheric pressure, liquid flow, diving depth, flying altitude, and much more.

However, current pressure sensors face the pitfall of not being sensitive enough to changes in addition to having a narrow sensing range Current pressure sensors are generally piezoelectric pressure sensors. To detect the pressure difference, piezoelectric film is disposed on a substrate in a pressure sensing assembly. When the substrate is bent by an external force, the piezoelectric film will deform, which generates a corresponding electrical signal, which the tester picks up to determine the applied force. Since the piezoelectric film is functions in connection with the substrate, if the substrate cannot be deformed arbitrarily after a force, or the bonding mode of the piezoelectric film to the bonding surface of the substrate is poor, the accuracy and sensitivity in the piezoelectric pressure sensor will decrease, creating a narrow sensing range and decreasing pressure detection accuracy.

### SUMMARY

This disclosure provides a method for manufacturing a porous pressure sensor, which can improve the sensitivity of the pressure sensor and increase the sensing range of the pressure sensor.

In an embodiment, the present application provides a porous pressure sensor manufactured by the method of manufacturing a porous pressure sensor according to the present application.

In an embodiment of the present application, there is provided a method of manufacturing a porous pressure sensor comprising the following operations: (1) providing a substrate; (2) forming a piezoelectric film on an upper surface of the substrate; (3) performing a porosification process on the piezoelectric film to form a porous pressure sensing layer; and (4) forming a first electrode and a second electrode on two opposite sides of an upper surface of the porous pressure sensing layer, respectively.

In an embodiment, the substrate is a solid flexible substrate composed of a silicon wafer, flexible polymer, metal, glass or mica, and the porous pressure sensing layer is a single layer or a multi-layer structure.

In an embodiment, the operation of forming a piezoelectric film on the upper surface of the substrate is preferably performed by a physical vapor deposition method, such as a sputtering method or an evaporation method, or a solution method.

In an embodiment, the operation of performing the porosification process on a piezoelectric film to form a porous pressure sensing layer is performed by the wet etching process, wherein an etching solution used in the wet etching process is a diluted acid/alkaline solution, such as hydrochloric acid (HCl), sulfuric acid (H2So4), nitric acid (HNo3), acetic acid (HC2H302) or sodium hydroxide (KOH) solution. The concentration of the etching solution is 0.1 mM and the etching time is one minute.

In an embodiment, the operation of performing the porosification process on the piezoelectric film to form a porous pressure sensing layer is performed by a heat treatment process, wherein the heat treatment process is performed in a tubular furnace or a box furnace, wherein a heating temperature is 500-600° C. and a heating time is one hour.

In an embodiment, the material of the piezoelectric film is one or more of metal oxide, nitride, polyvinylidene fluoride (PVDF), barium titanate BaTiO3, lead titanate PbTiO₃, lead zirconate PbZrO₃, or lead zirconate titanate PbZrTiO3 (PZT).

In an embodiment, the first electrode is made of one of gold, silver, platinum, and copper, and the second electrode is a transparent conductive film composed of indium tin oxide (ITO) or aluminum zinc oxide (AZO). In an embodiment, the first electrode is a transparent conductive film composed of indium tin oxide (ITO) or aluminum zinc oxide (AZO), and the second electrode is made of one of gold, silver, platinum, and copper. The first electrode and the second electrode act as an anode/cathode or a cathode/anode of the porous pressure sensor.

In addition, another embodiment of the present application is a porous pressure sensor manufactured by the method according to the present application.

The present application is described in further detail below with reference to the figures and embodiments.

### BRIEF DESCRIPTION OF DRAWINGS

FIGS. 1 (A)-(D) illustrate a method of manufacturing a porous pressure sensor and a pressure sensor manufactured by the method in a preferred embodiment of the present application.

FIG. 2 is a view showing a surface morphology of a zinc oxide film after the porous treatment in a preferred embodiment of the present application.

Wherein,

porous pressure sensor 100;

substrate 10;

piezoelectric film 11;

porous pressure sensing layer 12;

pore(s) 121;

first electrode 14;

second electrode 15.

### DESCRIPTION OF EMBODIMENTS

Various embodiments and aspects of the inventions will be described with reference to details discussed below, and the accompanying drawings will illustrate the various embodiments. The following description and drawings are illustrative of the invention and are not to be construed as limiting the invention. Numerous specific details are described to provide a thorough understanding of various embodiments of the present invention. However, in certain instances, well-known or conventional details are not described in order to provide a concise discussion of embodiments of the present inventions.

Reference in the specification to “one embodiment” or “an embodiment” means that a particular feature, structure, or characteristic described in conjunction with the embodiment can be included in at least one embodiment of the invention. The appearances of the phrase “in one embodiment” in various places in the specification do not necessarily all refer to the same embodiment.

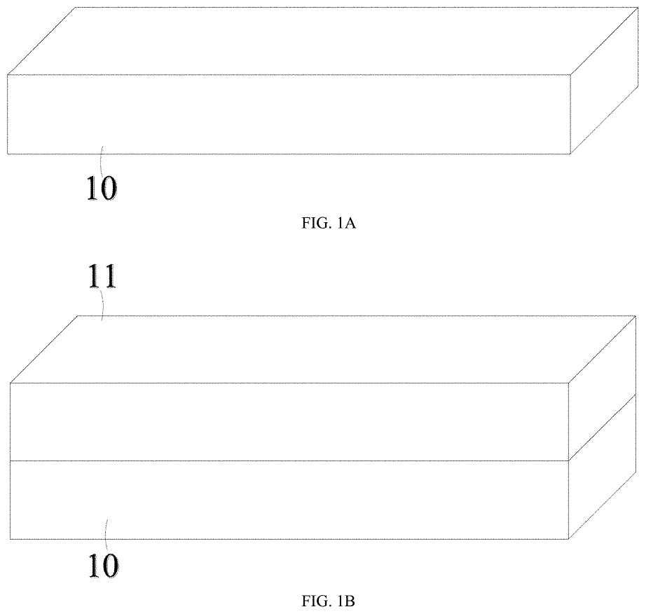

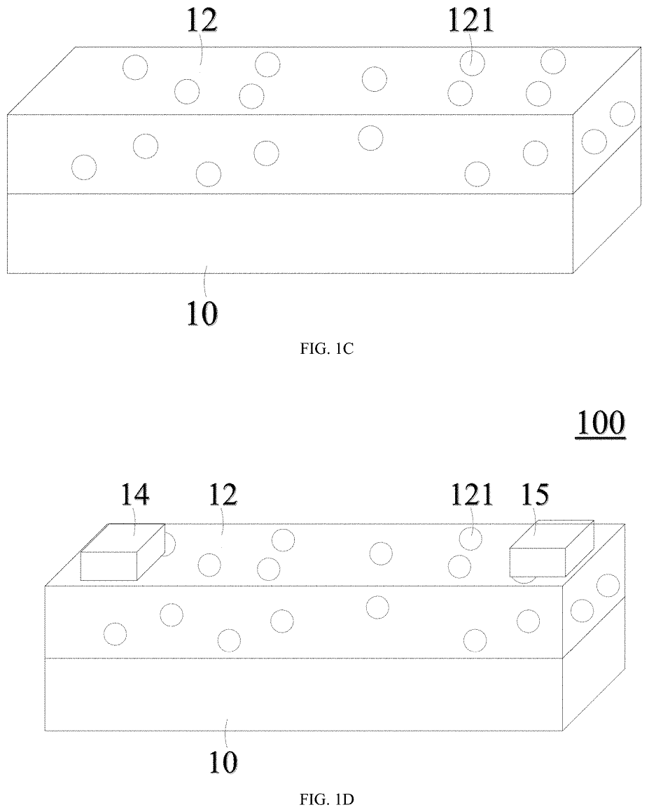

Referring to FIGS. 1 (A)-(D), a method of manufacturing a porous pressure sensor and a pressure sensor manufactured by the method are shown in a preferred embodiment of the present application. As shown in FIG. 1 (A), the method of manufacturing the porous pressure sensor of the present application comprises an operation of preparing a substrate 10, which is a solid flexible substrate, the material can be a silicon wafer, flexible polymer, metal, glass, or mica, or something similar.

Next, referring to FIG. 1 (B), a piezoelectric film 11 is grown on the substrate 10. The operation of growing a layer of the piezoelectric film 11 on the substrate 10 may use a physical vapor deposition (PVD) method or a solution synthesis method to grow a layer of the piezoelectric film 11 on the substrate 10, wherein the physical vapor deposition method may include, but is not limited to, sputtering method or evaporation method. The piezoelectric film 11 is made of a piezoelectric material, which may be a metal oxide (such as zinc oxide), a nitride (such as indium nitride, gallium nitride), polyvinylidene fluoride (PVDF), barium titanate BaTiO₃, lead titanate PbTiO₃, lead zirconate titanate PbPbZrO₃, lead zirconate titanate PbZrTiO₃ (PZT), or the like.

Next, referring to FIG. 1 (C), the piezoelectric film 11 is subjected to a porosification process to form a porous pressure sensing layer 12 comprising a plurality of pores 121. In a preferred embodiment of the present application, the porosification process may be an isotropic wet etching process, which, for example, uses a formulated dilute acidic/alkaline solution, and an acidic solution or an alkaline solution such as hydrochloric acid, sulfuric acid, nitric acid, acetic acid, sodium hydroxide (KOH) is used as an etching solution. In order to etch a plurality of pores 121 to form the porous pressure sensing layer 12, the piezoelectric film 11 is etched by controlling a concentration of the etching solution and an etching time. In this embodiment, the concentration of the etching solution is 0.1 mM; and the etching time is one minute.

In an embodiment of the present application, the porosification process may be a heat treatment process. In an embodiment, a reactant gas (such as oxygen) may be removed and the piezoelectric film 11 may be crystallized by heating, so as to cause the piezoelectric film 11 to generate the pores 121. In an embodiment, the heat treatment is performed in a tubular furnace or box furnace (neither shown), wherein a heating temperature is 500-600° C. and a heating time is one hour.

Next, referring to FIG. 1 (D), a first electrode 14 and a second electrode 15 are plated on opposite sides of the porous pressure sensing layer 12 to form a porous pressure sensor 100, as shown in FIG. 1 (D). The porous pressure sensing layer 12 may have a single layer structure or a multi-layer structure. The first electrode 14 and the second electrode 15 may be an anode and a cathode or a cathode and an anode of the porous pressure sensor 100, respectively. The porous pressure sensor 100 is composed of a substrate 10, a porous pressure sensing layer 12, a first electrode 14 and a second electrode 15, wherein the first electrode 14 is made of a metal such as gold, silver, platinum, copper, and the second electrode 15 is a transparent conductive film composed of indium tin oxide (ITO) or aluminum zinc oxide (AZO). However, the material selection of the first electrode 14 and the material selection of the second electrode 15 are not limited to the precise forms disclosed herein. For example, the first electrode 14 may be a transparent conductive film composed of indium tin oxide (ITO) or aluminum zinc oxide (AZO) or the like, and the second electrode 15 may be made of a metal such as gold, silver, platinum, copper, or the like.

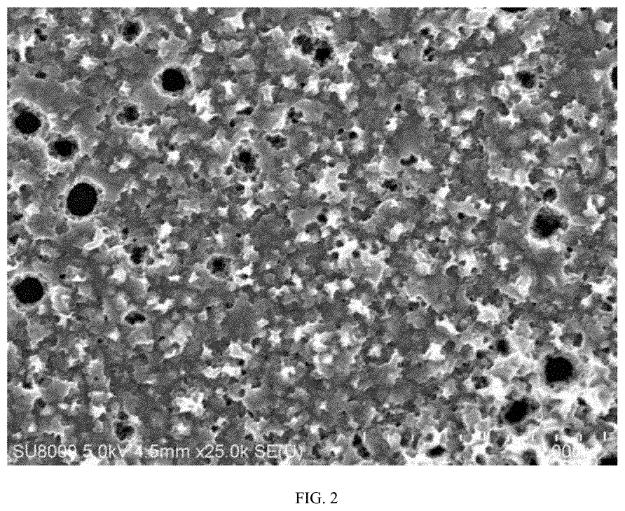

Referring to FIG. 2, which shows a surface morphology of a zinc oxide film after the porous treatment in a preferred embodiment of the present application. Herein, the material of the piezoelectric film 11 is represented by zinc oxide (ZnO). As can be seen by the scanning electron microscope photograph of FIG. 2, after performing a porosification process such as a wet etching or a heat treatment on the piezoelectric film 11, a plurality of pores 121 can be etched into the piezoelectric film 11, thereby forming a porous pressure sensing layer 12. A comparison result of the sensed pressure output value of the porous pressure sensing layer of the present application and the pressure sensing output value of the conventional non-porous pressure sensing layer is shown in the following table 1:

TABLE 1
Comparison of pressure sensing output values of the porous pressure
sensing layer of the present application with pressure sensing output
values of the conventional non-porous pressure sensing layer

| Category of pressure sensing layer | Pressure Sensing Output Values |
|---|---|
| Conventional Non-porous | 0.0038 A |
| Pressure Sensing Layer | |
| Porous Pressure Sensing Layer | 0.007 A |

As can be seen from Table 1, the pressure sensing output value of the porous pressure sensing layer of the present application is almost twice that of the conventional non-porous pressure sensing layer. Therefore, since the pressure sensing layer of the present application is a piezoelectric film which has been made porous, the pressure sensing layer of the present application has better sensing properties than a conventional piezoelectric film which has not been made porous.

Furthermore, the porous pressure sensor manufactured by the method according to the present application can also be used for other applications, such as power generation. Since the material of the piezoelectric film layer 11 must be a piezoelectric material, when a user applies force to the porous pressure detector of the present application, the pressure it receives can be converted into electrical energy output to achieve the purpose of power generation.

As mentioned above, in a method of manufacturing a porous pressure sensor according to the present application, a porous pressure sensing layer is formed by subjecting a porous treatment to a piezoelectric film, so as to the piezoelectric properties of the pressure sensor and the effect of pressure sensing can be improved. The porous pressure sensor manufactured by using the method of manufacturing the porous pressure sensor of the present application can have a better sensing sensitivity and a wider sensing range, that is, the pressure sensor can sense an increased range so that even a tiny amount of pressure can be sense. In addition, the porous pressure sensor manufactured by the method of manufacturing the porous pressure sensor according to the present application can be widely applied to many technical fields, such as medical treatment, personal wearing devices, and vehicle devices.

In the foregoing specification, embodiments of the invention have been described with reference to specific exemplary embodiments thereof. It will be evident that various modifications may be made thereto without departing from the broader spirit and scope of the invention as set forth in the following claims. The specification and drawings are, accordingly, to be regarded in an illustrative sense rather than a restrictive sense.

1. A method for manufacturing a porous pressure sensor, comprising:
providing a substrate;
forming a piezoelectric film on an upper surface of the substrate;
performing a porosification process on the piezoelectric film to form a porous pressure sensing layer; and
forming a first electrode and a second electrode on two opposite sides of an upper surface of the porous pressure sensing layer, respectively.

2. The method of claim 1, wherein the substrate is a solid flexible substrate composed one or more of a silicon wafer, flexible polymer, metal, glass, or mica.

3. The method of claim 1, wherein the porous pressure sensing layer is a single layer or a multi-layer structure.

4. The method of claim 1, wherein the forming the piezoelectric film on the upper surface of the substrate is performed by a physical vapor deposition method or a solution method.

5. The method of claim 4, wherein the physical vapor deposition method comprises a sputtering method or an evaporation method.

6. The method of claim 1, wherein the performing the porosification process on the piezoelectric film to form the porous pressure sensing layer is performed by a wet etching process, wherein an etching solution used in the wet etching process is composed one or more of a diluted hydrochloric acid, nitric acid, acetic acid, sulfuric acid, or sodium hydroxide (KOH) solution, and wherein a concentration of the etching solution is 0.1 mM, and wherein an etching time is one minute.

7. The method of claim 1, wherein the performing the porosification process on the piezoelectric film to form the porous pressure sensing layer is performed by a heat treatment process performed in a tubular furnace or a box furnace, wherein a heating temperature is 500-600° C. and a heating time is one hour.

8. The method of claim 1, wherein the material of the piezoelectric film is one or more of metal oxide, nitride, polyvinylidene fluoride (PVDF), barium titanate BaTiO3, lead titanate PbTiO₃, lead zirconate PbZrO₃, or lead zirconate titanate PbZrTiO₃ (PZT).

9. The method of claim 1, wherein the first electrode is comprised of one or more of gold, silver, platinum or copper, and the second electrode is a transparent conductive film composed of indium tin oxide (ITO) or aluminum zinc oxide (AZO).

10. The method of claim 1, wherein the first electrode is a transparent conductive film composed of indium tin oxide (ITO) or aluminum zinc oxide (AZO), and the second electrode is comprised of one or more of gold, silver, platinum or copper.

11. A porous pressure sensor manufactured by the method according to claim 1.
